(19) United States
(12) Patent Application Publication
(10) Pub. No.: US 2008/0105916 A1
(43) Pub. Date: May 8, 2008

(54) NONVOLATILE SEMICONDUCTOR MEMORY DEVICE AND MANUFACTURING METHOD THEREOF

(75) Inventor: Hiroshi WATANABE, Yokohama-Shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 11/774,891

(22) Filed: Jul. 9, 2007

(30) Foreign Application Priority Data
Nov. 7, 2006 (JP) 2006-301351

(51) Int. Cl. H01L 29/788; H01L 21/336

(52) U.S. Cl. 257/315; 438/257; 257/E29.3; 257/E21.409

(57) ABSTRACT

This disclosure concerns a memory device comprising an element formation area having a recess in a side of the active area (AA) so that a width of a part below an upper surface of the AA is smaller than a width of the upper surface of the AA in a cross section along a adjacent direction of STIs; a first gate insulation film on the AA; a floating gate on the first gate insulation film; a second gate insulation film on an upper and on a side surface of the floating gate; and a control gate on the upper surface and on the side surface of the floating gate via the second gate insulation film, wherein a width of the upper side of the floating gate is smaller than a width of the lower side of it in the cross section along the adjacent direction of the STI.

### CROSS-REFERENCE TO RELATED APPLICATION

This application is based upon and claims the benefit of priority from the prior Japanese Patent Applications No. 2006-301351, filed on Nov. 7, 2006, the entire contents of which are incorporated herein by reference.

### BACKGROUND OF THE INVENTION

1. Field of the Invention

The present invention relates to a nonvolatile semiconductor memory device and manufacturing method of a nonvolatile semiconductor memory device.

2. Related Art

A NAND flash memory can have a smaller cell area than a NOR flash or a DRAM, because a selection transistor controls a bit line. Therefore, a NAND flash memory can be manufactured at low cost.

However, when a NAND flash memory is miniaturized, a distance between memory cells (a width of an STI) is also made smaller along with the miniaturization of the memory cell size. This brings about a proximity effect of the memory cells, and causes the occurrence of interference between the memory cells. The interference between the memory cells works to average potentials of mutually adjacent floating gate electrodes. Therefore, a threshold value difference (ΔV_{TH}) between a state that data is written and a state that data is deleted becomes small. As a result, a data writing failure occurs. Further, due to the miniaturization of the memory cell size, increase of a leak current (S-factor) in the off state becomes a problem.

### SUMMARY OF THE INVENTION

A nonvolatile semiconductor memory device according to an embodiment of the present invention comprises a semiconductor substrate; a plurality of element isolation areas formed in the semiconductor substrate; an element formation area provided between the adjacent element isolation areas, the element formation area having a recess in a side surface of the element formation area so that a width of a part below an upper surface of the element formation area is smaller than a width of the upper surface of the element formation area in a cross section along a adjacent direction of the element isolation areas; a first gate insulation film provided on the element formation area; a floating gate electrode provided on the first gate insulation film; a second gate insulation film provided on an upper surface and on a side surface of the floating gate electrode; and a control gate electrode provided on the upper surface and on the side surface of the floating gate electrode via the second gate insulation film, wherein a width of the upper side of the floating gate electrode is smaller than a width of the lower side of the floating gate electrode in the cross section along the adjacent direction of the element isolation areas.

A method of manufacturing a nonvolatile semiconductor memory device according to an embodiment of the present invention comprises forming a first gate insulation film on a semiconductor substrate; depositing a floating gate electrode material on the first gate insulation film; forming a plurality of trenches reaching the semiconductor substrate by penetrating through the floating gate electrode material and the first gate insulation film, simultaneously etching a side surface of the floating gate electrode material to form a floating gate electrode so that a width of an upper side of the floating gate electrode material is smaller than a width of the lower side of the floating gate electrode material in the cross section along a array direction of the trenches, and simultaneously forming an element formation area having a recess in a side surface of the element formation area so that a width of a part below an upper surface of the element formation area is smaller than a width of the upper surface of the element formation area in a cross section along a array direction of the trenches; forming an element isolation area by filling an insulator into the trenches; forming a second gate insulation film on an upper surface and on a side surface of the floating gate electrode; and depositing a control gate electrode material on the second gate insulation film.

### BRIEF DESCRIPTION OF THE DRAWINGS

FIG. 1 is a plane view showing a NAND flash memory according to the first embodiment;

FIG. 2A is a cross-sectional diagram along a line A-A shown in FIG. 1;

FIG. 2B is a cross-sectional diagram along a line B-B shown in FIG. 1;

FIG. 3 is a cross-sectional diagram showing a manufacturing method of the memory;

FIG. 4 is a cross-sectional diagram showing a manufacturing method following FIG. 3;

FIG. 5 is a cross-sectional diagram showing a manufacturing method following FIG. 4;

FIG. 6A is a cross-sectional diagram showing a manufacturing method following FIG. 5;

FIG. 6B is a cross-sectional diagram showing other manufacturing method following FIG. 5;

FIG. 7 is a diagram showing a part at where an off-leak current flows;

FIG. 8 is a plane view showing a NAND flash memory according to the second embodiment;

FIG. 9 is a plane view showing a NAND flash memory according to the third embodiment; and

FIG. 10 shows a relationship between a self potential VFG of the floating gate electrode FG and a drain current Id flowing in the diffusion layer 40.

### DETAILED DESCRIPTION OF THE INVENTION

Embodiments of the present invention will be explained below with reference to the accompanying drawings. The present invention is not limited to the embodiments.

### First Embodiment

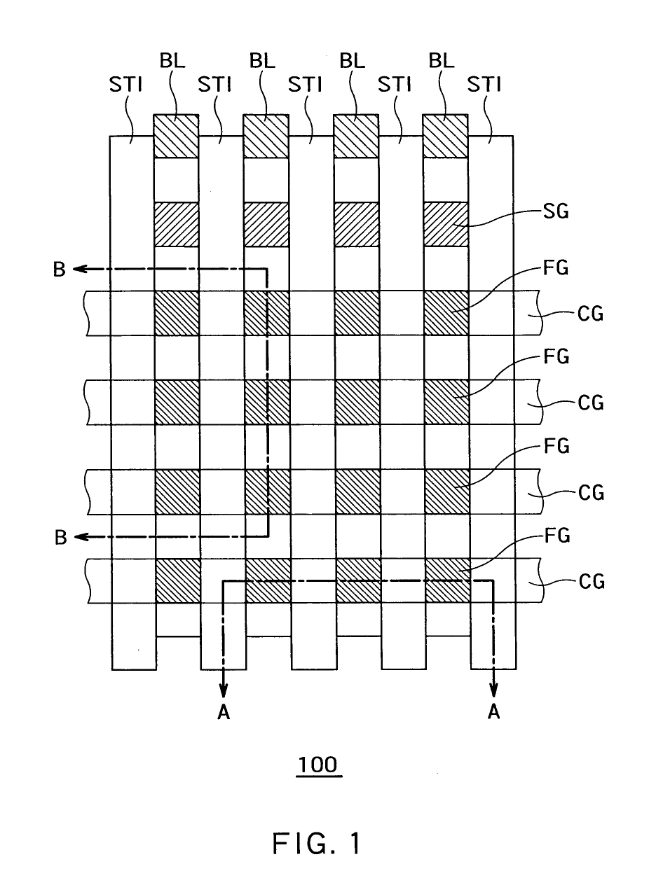

A NAND flash memory 100 shown in FIG. 1 includes bit lines BLs, a selection gate electrode SG, a floating gate electrode FG, a control gate electrode CG, and an STI (Shallow Trench Isolation) as an element isolation area. Because the selection gate electrode SG is provided, the bit line BL does not need to be provided in each memory cell. As a result, the NAND flash memory cell 100 is more advantageous for miniaturization than a DRAM and a NOR flash memory.

In general, according to a NAND flash memory requiring no formation of a bit line contact for each bit, a width between adjacent floating gate electrodes FGs becomes smaller along the miniaturization of the elements. This causes the strengthening of the proximity effect as described above.

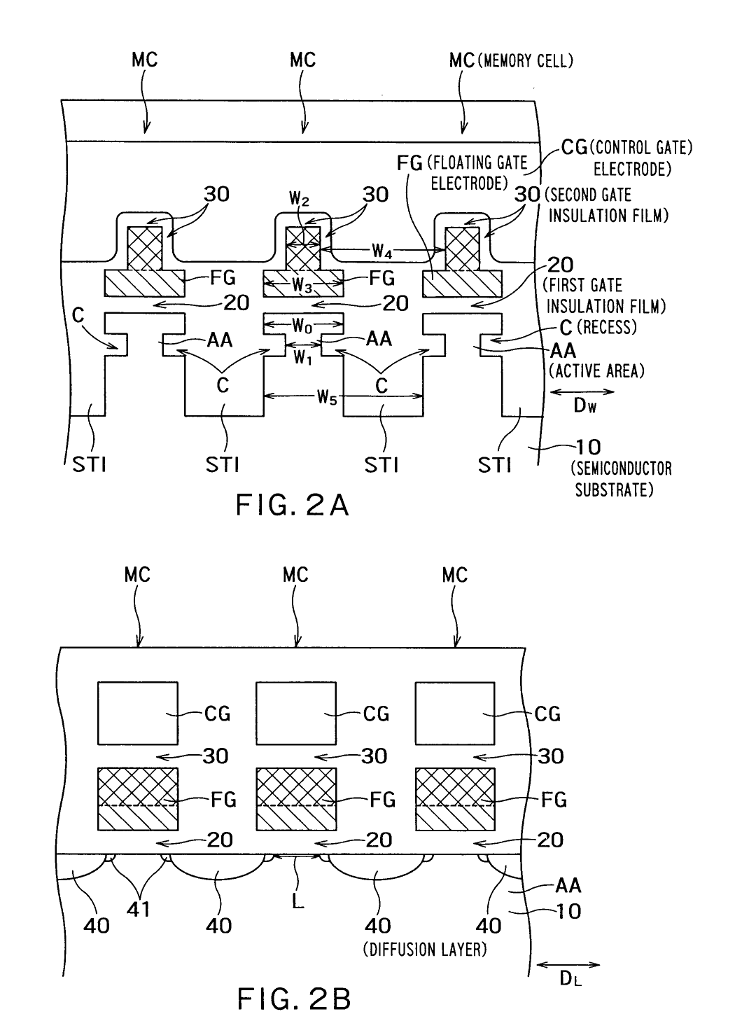

FIG. 2A is a cross-sectional diagram along a line A-A shown in FIG. 1. FIG. 2B is a cross-sectional diagram along a line B-B shown in FIG. 1. The memory 100 includes a semiconductor substrate 10, an active area AA as an element formation area, a first gate insulation film (tunnel insulation film) 20, a floating gate electrode FG, a second gate insulation film 30, a control gate electrode CG, and a diffusion layer 40.

Plural STIs are formed in a stripe shape on the semiconductor substrate 10 as shown in FIG. 1, and work as an element isolation area. An active area AA is provided between adjacent STIs. The first gate insulation film 20 is provided on the active area AA. A floating gate electrode FG is provided on the first gate insulation film 20. The second gate insulation film 30 is provided on the upper surface and on the side surface of the floating gate electrode FG. The control gate electrode CG is provided on the upper surface and on the side surface of the floating gate electrode FG via the second gate insulation film 30.

In the cross section of the structure in the STI adjacent direction (hereinafter, also referred to as a channel width direction) D_{w}, a width W1 as a part of the side of the active area AA is formed smaller than a width W0 of the upper surface of the active area AA. As a result, a recess C is formed at the side of the active area AA. In the cross section of the structure in the STI adjacent direction D_{w}, the floating gate electrode FG is formed in an inverted T shape. A width W2 of the upper side of the inverted T shape is smaller than a width W3 of the lower side of this inverted T shape. The control gate electrode CG is in between projections of the inverted T-shape floating gate electrodes FG.

As shown in FIG. 2B, the diffusion layer 40 is formed on the surface of the active area AA between the adjacent floating gate electrodes FGs. A channel length between the diffusion layers 40 is set as L. As shown in FIG. 2A, the channel width is W0. A channel length direction D_{L} is an extension direction of the STI, and this is a direction in which an electric charge flows between the diffusion layers 40. A channel width direction D_{W} is a direction crossing the channel length direction D_{L}. A reference numeral 41 denotes an extension layer.

As shown in FIG. 2A, because the width W2 of the upper part of the floating gate electrode FG is smaller than the width W3 of the lower part of this floating gate, a distance W4 between the adjacent floating gate electrodes FG becomes larger. Therefore, even if the distance between the memory cells MCs becomes smaller due to the miniaturization of the device, the distance W4 can be maintained large. Accordingly, the control gate electrode CG can be introduced to a deep position. As a result, the proximity effect between the memory cells can be suppressed, and a capacity coupling ratio of the first and the second gate insulation films 20 and 30 can be maintained.

In general, when a total width of the active area AA and the STI is W5, it is difficult to decrease this width W5 from the viewpoint of the lithography technique. Therefore, it is necessary to change a ratio of the line width to the space width in the width W5. According to the present embodiment, the space width is set large by forming small the width W2 of the upper part of the floating gate electrode FG, in the constant line-and-space width W5. With this arrangement, the present inventor has been successful in decreasing the proximity effect between the memory cells, by using the existing lithography technique.

According to the present embodiment, the floating gate electrode FG includes two kinds of materials. In other words, the portion (projection) above a broken line of the floating gate electrode FG consists of silicon germanium, and the portion (base) below the broken line consists of polysilicon. With this arrangement, the floating gate electrode FG can be easily formed in an inverted T shape, using a difference of speeds of etching the two kinds of materials, as described later.

According to the present embodiment, in the cross section of the structure in the direction D_{w}, the width of the upper side of the floating gate electrode FG is smaller than the width of the lower side of this floating gate electrode FG. Therefore, the control gate electrode CG can be filled without a gap to a sufficiently deep position between the adjacent floating gate electrodes FGs. With this arrangement, the proximity effect between the adjacent memory cells MCs can be suppressed.

In the cross section of the structure in the channel width direction D_{w} according to the present embodiment, the recess C is provided on the sidewall of the active area AA. Because of this recess C, the width W1 as a part of the side of the active area AA is formed smaller than the width W0 of the upper surface of the active area AA, in the cross section of the structure in the direction D_{w}. This recess C has a depth at the same position as that where an off-leak current flows within the active area AA. Specifically, it is ideal that the recess C is formed at the same depth position or at a deeper position than the depth of the source/drain diffusion layer 40. With this arrangement, the off-leak current can be decreased as described later.

The content of germanium in the active area AA is largest at the depth where the recess C is formed in the active area AA. In case that a germanium layer is introduced to the above depth of the active area AA, the recess C can be formed easily as described later. Because germanium is introduced to adjust the etching rate, when the etching gas is changed, germanium can be replaced with other element corresponding to the change of gas, to maintain the etching speed rate.

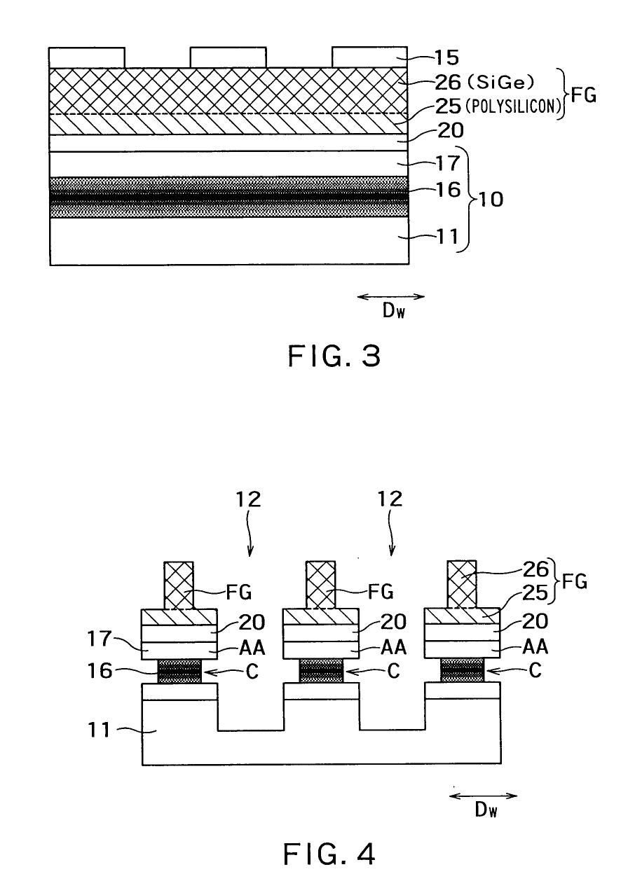

A method of manufacturing the memory 100 is explained next. First, the semiconductor substrate 10 shown in FIG. 3 is prepared. The semiconductor substrate 10 includes a semiconductor bulk 11, a silicon-germanium (SiGe) layer 16, and a semiconductor layer 17. The semiconductor layer 17 is provided on the silicon-germanium layer 16. The semiconductor bulk 11 and the semiconductor layer 17 consist of monocrystalline silicon, respectively, for example. The silicon-germanium layer 16 is a mixture layer of germanium and silicon. The semiconductor substrate 10 can be formed by ion-implanting germanium into the silicon substrate, and thermally treating the implanted result. Alternatively, the semiconductor substrate 10 can be formed by forming an epitaxial growth by mixing germanium on the semiconductor bulk 11, and further by epitaxially growing monocrystalline silicon not containing germanium. Silicon germanium has higher reactivity than silicon with an etching gas (SF₆ and C₄F₈, for example) of the silicon substrate. Germanium is introduced to match the depth of the source/drain diffusion layer 40. It is sufficient when the height of the silicon-germanium layer 16 matches the depth of the source/drain diffusion layer 40. The order of the implantation of germanium and the formation of the diffusion layer is not relevant. The silicon-germanium layer 16 has a thickness of 10 to 20 nm. When the silicon-germanium layer 16 has a larger thickness, the height becomes too close to the top surface the substrate 10, and this height interrupts the on-current. On the other hand, when the silicon-germanium layer 16 has a smaller thickness, the effect of decreasing the off-leak becomes smaller.

Next, materials of the first gate insulation film 20, the floating gate electrode FG, and a masking material 15 are formed in this order on the semiconductor substrate 10. The floating gate electrode FG includes two kinds of materials. In other words, an upper layer (projection) above a broken line of the floating gate electrode FG consists of a silicon-germanium layer 26, and a lower layer (base) below the broken line consists of a polysilicon layer 25.

Next, as shown in FIG. 4, plural trenches 12 are formed to reach the semiconductor bulk 11 by penetrating through the floating gate electrode FG, the first gate insulation film 20, the semiconductor layer 17, and the silicon-germanium layer 16. The trench 12 is formed by the RIE method, for example, using the mask material 15 as a mask. The etching gas is SF₆ or C₄F₈, for example.

An etching rate of the silicon-germanium layer 26 is faster than that of the polysilicon layer 25. In other words, the silicon-germanium layer 26 has higher reactivity than the polysilicon layer 25 with the etching gas. As a result, in the cross section of the structure in the array direction D_{w} of the trench 12, the silicon-germanium layer 26 is side-etched to a lateral direction, and the width of the silicon-germanium layer 26 is formed smaller than the width of the polysilicon layer 25. As a result, the width of the upper part of the floating gate electrode FG is formed smaller than the width of the lower part of this floating gate electrode FG.

Further, the etching rate of the silicon-germanium layer 16 is faster than that of the semiconductor layer 17 and the semiconductor bulk 11. As a result, in the cross section of the structure in the direction D_{w}, the silicon-germanium layer 16 is etched to a lateral direction, and the recess C is formed in a part of the side of the active area AA.

As explained above, the floating gate electrode FG and the active area AA can be formed in the same etching process of forming the trench.

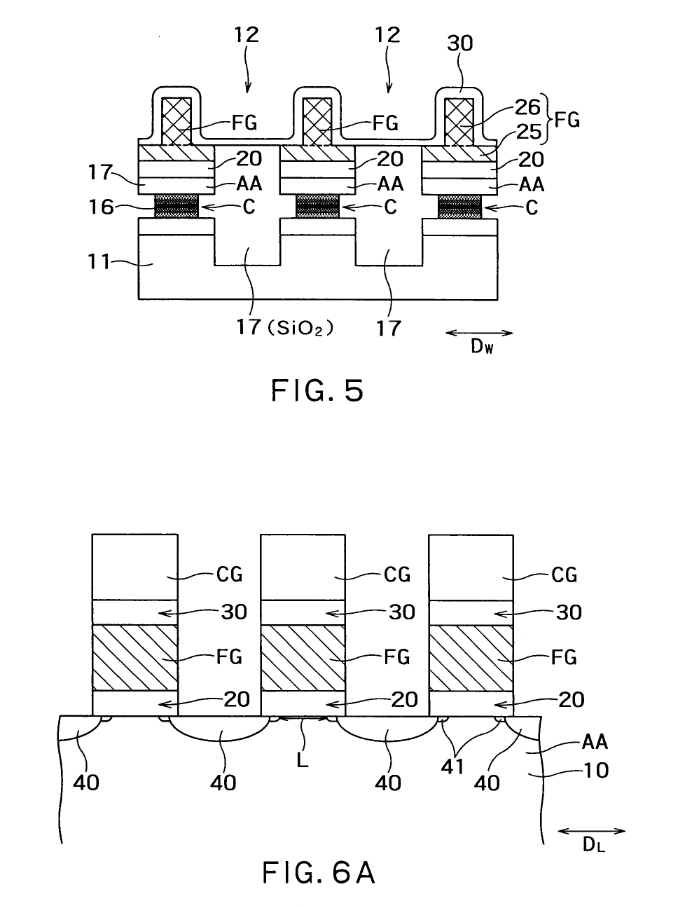

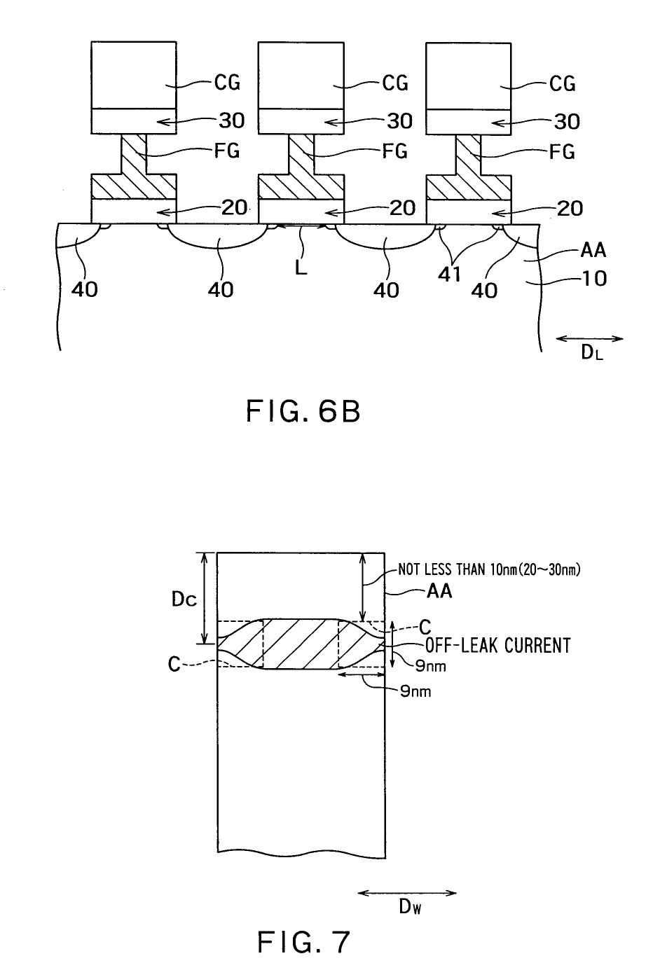

Next, the insulator 17 is deposited within the trench 12 as shown in FIG. 5. The insulator 17 includes a silicon oxide film, for example. In this case, the insulator 17 is deposited to the upper surface of the floating gate electrode FG. Thereafter, the insulator 17 is etched back to the middle of the sidewall of the floating gate electrode FG (to the upper surface level of the polysilicon layer 25, for example). By this etching back, the mask material 15 shown in FIG. 6 is also removed.

Next, the second gate insulation film 30 is formed on the upper surface and on the side surface of the floating gate electrode FG. The material of the control gate electrode CG is then deposited on the second gate electrode 30. Because the insulator 17 is etched back to the middle of the sidewall of the floating gate electrode FG, the material of the control gate electrode CG is introduced into between the side surfaces of the adjacent floating gate electrodes FGs in a self-alignment fashion.

Further, as shown in FIG. 6, the control gate electrode CG and the floating gate electrode FG are etched using the photolithography technique and the RIE method. FIG. 6 shows an element cross section of the structure in the channel length direction D_{L}. In this process, the floating gate electrode FG is individualized for each memory cell MC. Next, an impurity is ion-implanted into the active area AA and annealed, thereby forming the extension layer 41 and the source/drain diffusion layer 40. A protection layer 19 is deposited. Thereafter, a contact and a wiring are formed using a known method, thereby completing the memory 100.

A gas used for the RIE is selected from a one containing a halogen element, and is suitably selected from a one used for manufacturing a semiconductor. In the process of individualizing the floating gate electrode FG for each memory cell MC, when an etching gas having a fast etching rate of etching silicon germanium is used, the floating gate FG is formed as shown in FIG. 6B, like the etching in the D_{w} direction.

According to the present embodiment, a content rate of germanium relative to silicon is changed, and both the floating gate electrode FG and the recess C are formed using an etching selection rate of silicon and silicon germanium. Therefore, in the RIE process of forming the STI, both the inverted T-shape floating gate electrode FG and the recess C can be formed. In other words, according to the manufacturing method of the present embodiment, the STI, the inverted T-shape floating gate electrode FG, and the recess C of the active area AA can be formed simultaneously, in one RIE process. As explained above, the method of manufacturing a memory according to the present embodiment matches the conventional method of manufacturing a memory, and can be easily started using the existing process.

According to the present embodiment, in the cross section of the structure in the direction D_{w}, the width of the upper side of the floating gate electrode FG is smaller than the width of the lower side of this floating gate electrode FG. Therefore, a film can be formed in good coverage of the floating gate electrode FG. As a result, the control gate electrode CG can be easily filled into a sufficiently deep position between the adjacent floating gate electrodes FGs.

As shown in FIG. 7, in general, the off-leak current flows at a position of a certain depth Dc from the surface of the active area AA. It is known that generally the depth Dc of the off-leak current is at a position equivalent to or deeper than the depth of the source/drain diffusion layer 40 formed in the source/drain area, although the depth Dc depends on the impurity profile of the active area AA. According to the present embodiment, the recess C is provided at a position of the same depth as that where the off-leak current flows within the active area AA. As a result, the off-leak current flowing near the sidewall of the active area AA can be removed.

More specifically, the recess C is formed in the depth of 10 nm or more blow the surface of the active area AA. Preferably, the recess C is formed in the depth of 20 nm to 30 nm from the surface of the active area AA. Because the depth of the source/drain diffusion layer 40 is about 20 nm from the surface of the active area AA, the recess C is formed in the same depth as that of the source/drain diffusion layer 40. The opening width and the length of the recess C are approximately 9 nm, respectively. It is important to notice that even when the recess C is formed in the depth of 10 nm or more (20 nm to 30 nm) from the surface of the active area AA, no adverse influence is given to the on-current flowing through the surface of the active area AA. The on-current flows at a shallow position of less than 10 nm from the surface of the active area AA. Therefore, when the recess C is formed at a deeper position than the surface of the active area AA, the on-current does not decrease.

When the width W3 of the bottom of the floating gate electrode FG is set substantially equal to the width W0 of the upper surface of the active area AA, or when W3 is set larger than W0, that is, when the facing area of the floating gate electrode FG and the active area AA is not decreased, the off-leak does not increase. Therefore, when the recess C is provided, the off-leak current can be substantially decreased. In other words, the S-factor can be improved by combining the inverted T-shape floating gate FG and the recess C.

### Second Embodiment

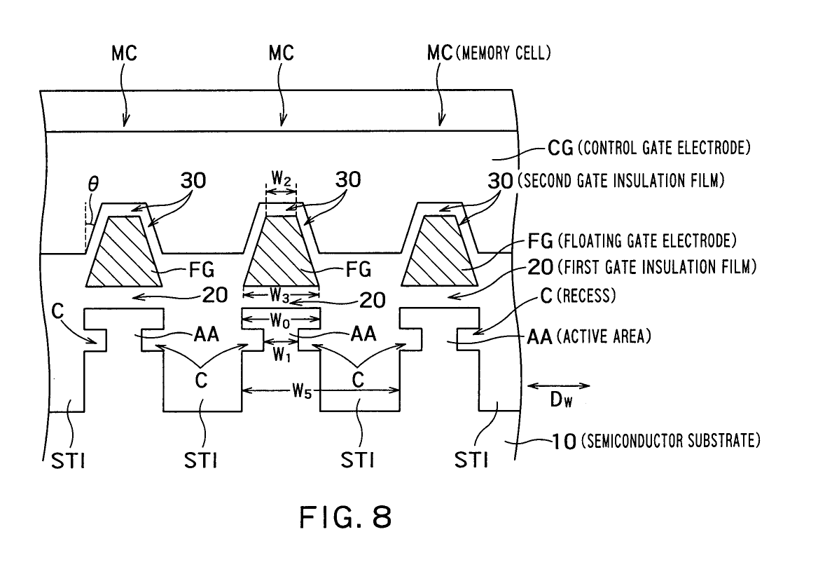

In a NAND flash memory 200 according to a second embodiment shown in FIG. 8, the floating gate electrode FG is formed in a trapezoidal shape in the cross section of the structure in the direction D_{w}. Other structures of the NAND flash memory according to the second embodiment are similar to those according to the first embodiment.

The upper side and the lower side of the floating gate electrode FG are parallel, and the width W3 of the lower side is smaller than the width W2 of the upper side. When the width W3 of the lower side is set substantially equal to the width W0 of the upper side of the active area AA, or when W3 is set larger than W0, the off-leak does not increase. Therefore, when the recess C is provided, the off-leak path becomes smaller, like in the first embodiment. As a result, the off-leak current can be decreased.

Usually, when the etching condition is adjusted, the sidewall of the floating gate electrode FG becomes in a forward tapered shape. Namely, the width of the side of the floating gate electrode FG becomes thicker toward the bottom from the upper part.

As another method of adjusting a slope θ of the forward taper, other element (germanium, for example) can be introduced. For example, a mixture rate of germanium contained in the deposit gas is set low at the beginning of the process of depositing the floating gate electrode material, and thereafter, the mixture rate of germanium is set gradually higher. As a result, the concentration of germanium becomes low at the bottom of the floating gate electrode FG, and becomes higher toward the upper part. An etching gas having high reactivity with germanium than with silicon is selected. With this arrangement, the slope θ of the forward taper becomes large.

Other manufacturing methods according to the second embodiment can be identical to the manufacturing method according to the first embodiment. As a result, effects similar to that of the first embodiment can be obtained from the second embodiment.

### Third Embodiment

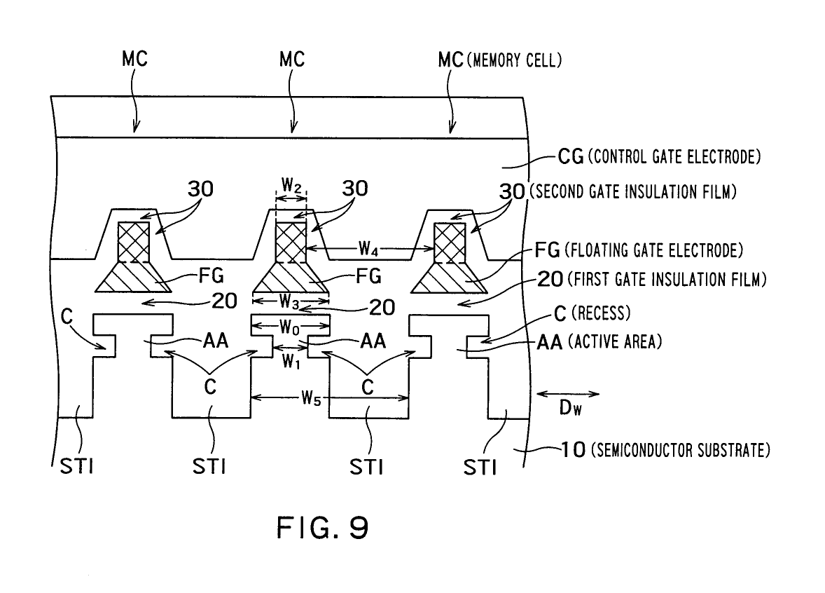

In a NAND flash memory 300 according to a third embodiment shown in FIG. 9, the bottom (base) of the floating gate electrode FG is formed in a sequentially tapered shape in the cross section of the structure in the direction D_{w}. Other structures of the NAND flash memory according to the third embodiment can be similar to those according to the first embodiment.

The width W3 of the lower side of the floating gate electrode FG is larger than the width W2 of the upper side of this floating gate electrode FG. When the width W3 of the lower side is set substantially equal to the width W0 of the upper side of the active area AA, or when W3 is set larger than W0, the off-leak does not increase. Therefore, when the recess C is provided, the off-leak current can be decreased, like in the first embodiment.

In order to adjust the slope θ of the forward taper of the base of the floating gate electrode FG, the mixture rate of germanium contained in the deposit gas is decreased at the beginning of the process of depositing the floating gate electrode materials, and thereafter, the mixture rate of germanium is gradually increased. In the middle of the deposit process, the mixture rate of germanium is set constant. With this arrangement, the concentration of germanium is low at the bottom of the base of the floating gate electrode FG, and becomes higher toward the upper part of the base. Further, the concentration of germanium at the projection of the floating gate electrode FG is constant. As a result, only the side of the base is etched to become sequentially tapered, at the time of forming the trench 12 in FIG. 4.

Other manufacturing method according to the third embodiment can be similar to the manufacturing method according to the first embodiment. As a result, effects similar to that of the first embodiment can be obtained from the third embodiment.

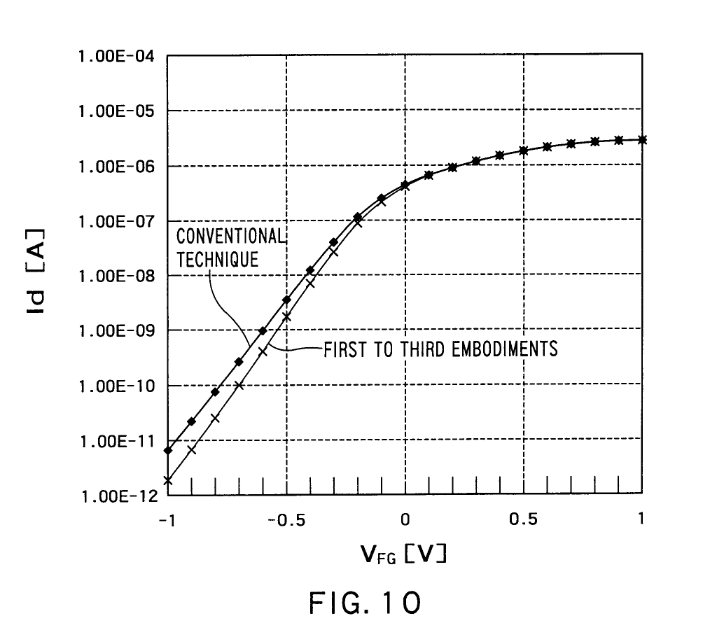

FIG. 10 shows a relationship between a self potential VFG of the floating gate electrode FG and a drain current Id flowing in the diffusion layer 40. FIG. 10 shows a result of using the memory cells MCs having the recess C shown in FIG. 7. It can be known from this graph that the memory cell MC becomes in the off state when the gate voltage VFG is at about −0.75 V.

It is clear from this graph that the Id according to the first to the third embodiments is lower than the Id according to the conventional example. This means that the off-leak current according to the first to the third embodiments is smaller than that according to the conventional example.

According to the first to the third embodiments, the recess C is formed at a position where the off-leak current flows, near the sidewall of the active area AA. As a result, the increase in the off-leak current can be prevented.

On the other hand, according to these embodiments, in the cross section of the structure in the direction D_{w}, the width W3 of the bottom of the floating gate electrode FG is equal to or larger than the width W0 of the upper side of the active area AA. As a result, because the bottom surface of the floating gate electrode FG faces the total upper surface of the active area AA, the off-leak current does not increase. As explained above, when the floating gate electrode FG having the wide bottom is combined with the recess C of the active area AA, the S-factor of the memory cell MC can be made smaller. As a result, the reading characteristics of the memory cells MCs can be improved.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. A nonvolatile semiconductor memory device comprising:
a semiconductor substrate;
a plurality of element isolation areas formed in the semiconductor substrate;
an element formation area provided between the adjacent element isolation areas, the element formation area having a recess in a side surface of the element formation area so that a width of a part below an upper surface of the element formation area is smaller than a width of the upper surface of the element formation area in a cross section along a adjacent direction of the element isolation areas;
a first gate insulation film provided on the element formation area;
a floating gate provided on the first gate insulation film;
a second gate insulation film provided on an upper surface and on a side surface of the floating gate; and
a control gate electrode provided on the upper surface and on the side surface of the floating gate via the second gate insulation film, wherein
a width of the upper side of the floating gate is smaller than a width of the lower side of the floating gate in the cross section along the adjacent direction of the element isolation areas.

2. The device according to claim 1, wherein
the floating gate has first element and second elements, and a content of the first element of the floating gate becomes higher at an upper part than at the bottom of the floating gate.

3. The device according to claim 2, wherein
the first element is germanium, and the second element is silicon.

4. The device according to claim 1, wherein
the floating gate is formed in an inverted T shape.

5. The device according to claim 4, wherein
a projection at an upper part of the inverted T-shape floating gate consists of silicon germanium, and a base of a lower part of the floating gate consists of polysilicon.

6. The device according to claim 1, wherein
the floating gate is formed in a trapezoidal shape, and an upper side and a lower side of the floating gate are in parallel.

7. The device according to claim 1, wherein
the element formation area contains first and second elements, and
a content rate of the first element is largest at a depth where the recess is formed in the cross section along the adjacent direction of the element isolation areas.

8. The device according to claim 7, wherein
the first element is germanium, and the second element is silicon.

9. The device according to claim 1, further comprising diffusion layers provided at both sides of the floating gate, wherein
in the cross section along the adjacent direction of the element isolation areas, a depth at which the recess is formed is equal to or deeper than the depth of the diffusion layers at the end of the floating gate.

10. The device according to claim 1, wherein
the nonvolatile semiconductor memory device is a NAND flash memory.

11. A method of manufacturing a nonvolatile semiconductor memory device comprising:
forming a first gate insulation film on a semiconductor substrate;
depositing a floating gate material on the first gate insulation film;
forming a plurality of trenches reaching the semiconductor substrate by penetrating through the floating gate material and the first gate insulation film, simultaneously etching a side surface of the floating gate material to form a floating gate so that a width of an upper side of the floating gate material is smaller than a width of the lower side of the floating gate material in the cross section along a array direction of the trenches, and simultaneously forming an element formation area having a recess in a side surface of the element formation area so that a width of a part below an upper surface of the element formation area is smaller than a width of the upper surface of the element formation area in a cross section along an array direction of the trenches;
forming an element isolation area by filling an insulator into the trenches;
forming a second gate insulation film on an upper surface and on a side surface of the floating gate; and
depositing a control gate electrode material on the second gate insulation film.

12. The method according to claim 11, wherein
at the time of depositing the floating gate material, a lower-layer material is deposited on the first gate insulation film, and next an upper-layer material having higher reactivity than the lower-layer material with an etching gas of the floating gate material is deposited on the lower-layer material, and
at the time of forming the trenches, the upper-layer material and the lower-layer material are etched, and the side surface of the floating gate material is etched so that a width of an upper side of the floating gate material becomes smaller than a width of a lower side of the floating gate material in the cross section along an array direction of the trenches.

13. The method according to claim 11, wherein
at the time of depositing the floating gate material, a mixture rate of first element contained in the deposit gas is set lower than that of second element at the beginning of the process of depositing the floating gate material, and thereafter, the mixture rate of the first element is gradually increased and the mixture rate of the second element is gradually decreased, the second element having lower reactivity than the first element with the etching gas,
at the time of forming the trenches, the side surface of the floating gate material is etched so that a width of the upper side of the floating gate material becomes smaller than a width of the lower side of the floating gate material in the cross section along the array direction of the trenches.

14. The method according to claim 13, wherein
the first element is germanium, and the second element is silicon.

15. The method according to claim 11, wherein
a third element having higher reactivity than the semiconductor substrate with the etching gas of the semiconductor substrate is implanted into the semiconductor substrate to form a mixture layer introduced with the third element in the semiconductor substrate, and
at the time of forming the trenches, the trenches are formed to reach the semiconductor substrate below the mixture layer by penetrating through the floating gate material, the first gate insulation film, the semiconductor substrate and the mixture layer, and
a width of the side of the element formation area is formed smaller than a width of the upper surface of the element formation area at the portion of the mixture layer in the cross section along the array direction of the trenches.

16. The method according to claim 15, wherein
the semiconductor substrate is a silicon substrate, and
the third element is germanium.

17. The method according to claim 1, wherein
after forming the floating gate, diffusion layers are formed at both sides of the floating gate, and
the recess formed on the side surface of the element formation area is equal to or deeper than the depth of the diffusion layers at the end of the floating gate.

18. The method according to claim 11, wherein
the nonvolatile semiconductor memory device is a NAND flash memory.

19. The method according to claim 11, wherein
both the element formation area and the floating gate are formed in the same etching process.
